(19) United States
(12) Patent Application Publication
(10) Pub. No.: US 2026/0255759 A1
(43) Pub. Date: Aug. 27, 2026

(54) DISPLAY DEVICE, METHOD OF MANUFACTURING DISPLAY DEVICE, AND ELECTRONIC DEVICE INCLUDING DISPLAY DEVICE

(71) Applicant: Samsung Display Co., Ltd., Yongin-Si (KR)

(72) Inventors: Jong Hyeon CHOI, Yongin-si (KR); Jeong Ho HWANG, Yongin-si (KR)

(21) Appl. No.: 19/448,651

(22) Filed: Jan. 14, 2026

(30) Foreign Application Priority Data
Feb. 25, 2025 (KR) 10-2025-0024489

(51) Int. Cl. H10H 29/80; H10H 29/01; H10K 59/12; H10K 59/80

(52) U.S. Cl. CPC H10H 29/842; H10H 29/012; H10H 29/034; H10K 59/1201; H10K 59/871

(57) ABSTRACT

A display device includes a display panel including a display area and a non-display area around the display area; and a coating layer disposed on the display panel. The coating layer has a top surface including a first plane at a central portion of the coating layer, and a second plane inclined with respect to the first plane at at least one edge of the coating layer and overlapping only with the non-display area.

### CROSS-REFERENCE TO RELATED APPLICATION

This application claims priority to and the benefit of Korean Patent Application No. 10-2025-0024489 filed in the Korean Intellectual Property Office on February 25, 2025, the entire contents of which are incorporated herein by reference.

### BACKGROUND

### 1. Field

The present disclosure relates to a display device. Specifically, the present disclosure relates to a display device, a method of manufacturing the same, and an electronic device including the same.

### 2. Description of the Related Art

Recently, as interest in information display has increased, research and development on display devices are continuously being conducted.

The above description is only for the purpose of facilitating an understanding of the background art of the technical ideas of the present disclosure, and thus it cannot be understood as content corresponding to the prior art known to those skilled in the art of the present disclosure.

### SUMMARY

A feature to be achieved by the present disclosure is to provide a display device with improved reliability.

Another feature to be achieved by the present disclosure is to provide a method of manufacturing the display device.

Another feature to be achieved by the present disclosure is to provide an electronic device including the display device.

The features of the present disclosure are not limited to the above-mentioned features, and other technical features that are not mentioned may be clearly understood by those skilled in the art from the following description.

A display device according to embodiments of the present disclosure includes a display panel including a display area and a non-display area around the display area; and a coating layer disposed on the display panel. The coating layer has a top surface including a first plane at a central portion of the coating layer, and a second plane inclined with respect to the first plane at at least one edge of the coating layer and overlapping only with the non-display area.

In an embodiment, a distance from the display panel to the second plane may be smaller than or equal to a distance from the display panel to the first plane.

In an embodiment, the distance from the display panel to the second plane may decrease as a distance from the first plane increases.

In an embodiment, the first plane and the second plane may form a boundary line at a portion connected to each other, and the top surface of the coating layer may extend from the first plane to the second plane.

In an embodiment, a width of the display panel in a first direction may be a same as a width of the coating layer in the first direction.

In an embodiment, an end of an edge of the coating layer on which the second plane of the coating layer exists and an end of the display panel may coincide with each other.

In an embodiment, a roughness of the first plane may be different from a roughness of the second plane.

In an embodiment, the roughness of the second plane may be greater than the roughness of a first plane.

In an embodiment, the coating layer may include a first resin layer disposed in the central portion on the display panel; and a second resin layer disposed on an edge of the display panel and in contact with the first resin layer.

In an embodiment, the first resin layer may have the first plane as an upper surface, and the second resin layer may have the second plane as an upper surface.

In an embodiment, a boundary line between the first plane and the second plane may be a part of a boundary surface between the first resin layer and the second resin layer.

In an embodiment, each of the first resin layer and the second resin layer may include a urethane acrylate, and a degree of hardening of the second resin layer may be greater than a degree of hardening of the first resin layer.

In an embodiment, a boundary surface between the first resin layer and the second resin layer may be a curved surface.

In an embodiment, the display panel and the coating layer may be in direct contact with each other.

In an embodiment, the display device may include no optical film between the display panel and the coating layer.

A method of manufacturing a display device according to embodiments of the present disclosure includes forming a display panel including a display area and a non-display area around the display area; and forming a coating layer having a top surface including a first plane at a central portion of the coating layer on the display panel, and a second plane inclined with respect to the first plane and overlapping only with the non-display area at at least one edge of the coating layer.

In an embodiment, forming the coating layer may include forming a first resin layer disposed in the central portion on the display panel and having the first plane as an upper surface, and a second resin layer disposed at the edge on the display panel and having the second plane as an upper surface.

In an embodiment, forming the first resin layer and the second resin layer may include surrounding at least one side surface of the display panel with a jig, and pressing the at least one side surface of the display panel with the jig; forming a preliminary resin layer on an edge of the display panel inside the jig; removing the jig; forming the first resin layer in a central portion of the display panel inside the preliminary resin layer; and removing a portion of the preliminary resin layer to form the second resin layer having the second plane inclined from the first plane.

In an embodiment, the first resin layer may be formed to have a thickness smaller than a thickness of the preliminary resin layer and larger than a thickness of the second resin layer.

In an embodiment, forming the preliminary resin layer may include forming a first non-hardened layer with urethane acrylate; and hardening the first non-hardened layer, and forming the first resin layer may include forming a second non-hardened layer with urethane acrylate; and hardening the second non-hardened layer.

In an embodiment, a part of the preliminary resin layer may be cut and removed using a laser.

An electronic device according to embodiments of the present disclosure includes one or more processors; and a display device configured to display an image under a control of the one or more processors. The display device includes: a housing member; a display panel disposed inside the housing member and including a display area and a non-display area around the display area; a coating layer disposed inside the housing member, disposed on the display panel, and having a top surface including a first plane at a central portion of the coating layer and a second plane inclined with respect to the first plane at at least one edge of the coating layer and overlapping only with the non-display area; and a polarizing film disposed inside the housing member and disposed on the coating layer.

In an embodiment, the housing member may cover a side surface of each of the display panel, the coating layer, and the polarizing film.

In an embodiment, the electronic device may further include a sealing member disposed between the housing member and both the display panel and the coating layer on a plane, the sealing member surrounding the display panel and coating layer.

In an embodiment, a width of the polarizing film in a first direction may be greater than a width of the coating layer in the first direction.

In an embodiment, the housing member may cover a side surface of each of the display panel and the coating layer and a portion of an upper surface of the polarizing film.

In an embodiment, the housing member may be in contact with a side surface of each of the display panel and the coating layer, and may not be in contact with an upper surface of the coating layer.

Specific details of other embodiments are included in the detailed description and drawings.

According to the above-described embodiment, the coating layer is disposed on the display panel to protect the display panel, and the second plane inclined from the first plane, which is a flat portion of the coating layer, overlaps only with the non-display area, so that the coating layer may protect the display panel without any problem of poor visibility and improve the impact resistance of the display device. In addition, in case that the coating layer is disposed to protect the display panel, because a member other than the coating layer is not required, the thickness of the display device may be reduced.

The second resin layer formed on the edge of the display device and the first resin layer formed inside the second resin layer are separately formed, so that the coating layer may be directly formed on the display panel without a separate member. That is, the display device may not include a separate layer or member such as an optical film between the display panel and the coating layer. In addition, the coating layer without edge beads may be formed on the edge.

In case that the coating layer is formed to compensate for the impact resistance of the display panel, because only one layer of the coating layer is disposed on the display panel and a separate configuration is not required, the product thickness is reduced, and the manufacturing process may be simplified. As a result, manufacturing cost for manufacturing a product is reduced, and thus manufacturing efficiency may be improved. In addition, because the coating layer is entirely coated on the display panel and is formed by cutting the edges of the coating layer located in the non-display area, visibility defects due to lifting of the configuration on the display panel may be improved.

Effects according to embodiments are not limited by what is illustrated above, and more diverse effects are included in the present specification.

### BRIEF DESCRIPTION OF THE DRAWINGS

FIG. 1 is a block diagram illustrating an embodiment of a display device.

FIG. 2 is a block diagram illustrating an embodiment of any one of the sub-pixels of FIG. 1.

FIG. 3 is a plan view illustrating an embodiment of the display device of FIG. 1.

FIG. 4 is a cross-sectional view illustrating an embodiment of the display device of FIG. 3.

FIG. 5 is an enlarged cross-sectional view illustrating a region A of FIG. 4.

FIG. 6 is a cross-sectional view illustrating an embodiment of the display panel of FIG. 4.

FIGS. 7, 8, 9, 10, 11, 12, 13, and 14 are diagrams illustrating a method of manufacturing a display device according to an embodiment of the present disclosure.

FIGS. 15 and 16 are cross-sectional views illustrating a method of manufacturing a display device according to a comparative example.

FIGS. 17, 18, 19, and 20 are diagrams illustrating a method of manufacturing a display device according to an embodiment of the present disclosure.

FIG. 21 is a block diagram of an electronic device according to an embodiment.

FIG. 22 is a schematic diagram of an electronic device according to various embodiments.

FIG. 23 is a cross-sectional view of a display device included in an electronic device according to an embodiment.

FIG. 24 is a cross-sectional view of a display device included in an electronic device according to an embodiment.

FIG. 25 is a cross-sectional view of a display device included in an electronic device according to an embodiment.

### DETAILED DESCRIPTION OF THE EMBODIMENTS

The present disclosure is capable of making various changes and having various forms, and specific embodiments are illustrated in the drawings and will be described in detail in the description. However, this is not intended to limit the present disclosure to any specific disclosure form, but it is to be understood that the present disclosure includes all modifications, equivalents, or alternatives within the spirit and scope of the present disclosure.

Similar reference numerals have been used for similar components in describing each figure. In the accompanying drawings, the dimensions of the structures are shown to be larger than in practice for clarity of the present disclosure. The terms first, second, and the like may be used to describe various components, but the components should not be limited by the terms. The terms are used only for the purpose of distinguishing one component from another. For example, a first component may be termed a second component, and similarly, a second component may also be termed a first component, without departing from the scope of the present disclosure.

In this application, the term “comprise” or “have” or the like is intended to designate the presence of a feature, a number, a step, an operation, a component, a part, or a combination thereof described in the specification, and should be understood as not precluding the presence or possibility of addition of one or more other features or numbers, steps, operations, components, parts, or combinations thereof. When a portion of a layer, a film, a region, a plate, or the like is “on” another portion, this includes not only the case where the other portion is “directly on” but also the case where there is another portion in the middle. In the present specification, when a portion such as a layer, a film, a region, or a plate is formed on another portion, the formed direction is not limited to an upper direction, and includes a side surface or a lower direction. Conversely, when a portion of a layer, a film, a region, a plate, or the like is “below” another portion, this includes not only the case where the other portion is “right below” but also the case where there is another portion in the middle.

Hereinafter, embodiments of the present disclosure and other matters necessary for a person skilled in the art to easily understand the contents of the present disclosure will be described in detail with reference to the accompanying drawings. In the following description, the singular includes the plural unless the context clearly indicates the singular.

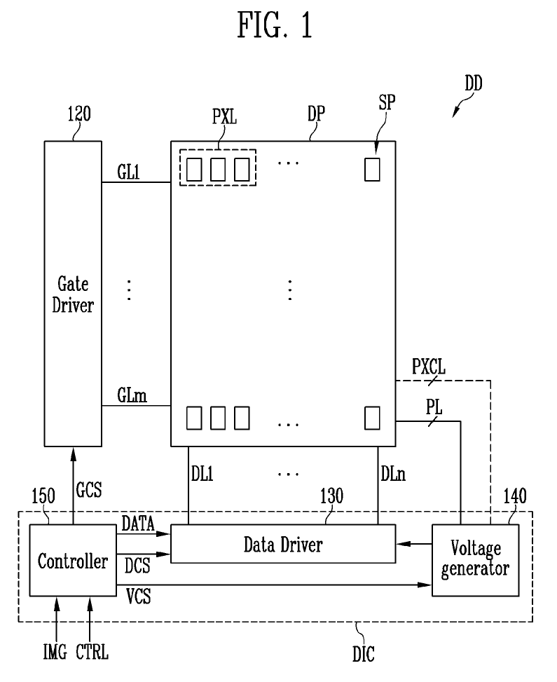

FIG. 1 is a block diagram illustrating an embodiment of a display device DD.

Referring to FIG. 1, the display device DD may include a display panel DP, a gate driver 120, a data driver 130, a voltage generator 140, and a controller 150.

The display panel DP includes sub-pixels SP. The sub-pixels SP may be connected to the gate driver 120 through first to m-th gate lines GL1 to GLm. The sub-pixels SP may be connected to the data driver 130 through first to n-th data lines DL1 to DLn.

The sub-pixels SP may generate light of two or more colors. For example, each of the sub-pixels SP may generate light such as red, green, blue, cyan, magenta, yellow, or the like.

Two or more sub-pixels among the sub-pixels SP may constitute one pixel PXL. For example, the pixel PXL may include three sub-pixels as shown in FIG. 1. As such, the pixel PXL may emit light of various colors and various luminances according to a combination of light emitted from sub-pixels included in the pixel PXL.

The gate driver 120 is connected to the sub-pixels SP arranged in a row direction through the first to m-th gate lines GL1 to GLm. The gate driver 120 may output gate signals to the first to m-th gate lines GL1 to GLm in response to a gate control signal GCS. In embodiments, the gate control signal GCS may include a start signal indicating a start of each frame, a horizontal synchronization signal, and the like.

The gate driver 120 may be located on one side of the display panel DP. However, embodiments are not limited thereto. For example, the gate driver 120 may be divided into two or more drivers that are physically and/or logically divided, and the drivers may be located on one side of the display panel DP and another side of the display Panel DP opposite to the one side. As such, the gate driver 120 may be located around the display panel DP in various forms according to embodiments.

The data driver 130 is connected to the sub-pixels SP arranged in a column direction through the first to n-th data lines DL1 to DLn. The data driver 130 receives image data DATA and a data control signal DCS from the controller 150. The data driver 130 operates in response to the data control signal DCS. In embodiments, the data control signal DCS may include a source start signal, a source shift clock, a source output enable signal, and the like.

The data driver 130 may receive voltages from the voltage generator 140. The data driver 130 may apply data signals having grayscale voltages corresponding to the image data DATA to the first to n-th data lines DL1 to DLn using the received voltages. When a gate signal is applied to each of the first to m-th gate lines GL1 to GLm, the data signals corresponding to the image data DATA may be applied to the data lines DL1 to DLn. Accordingly, the sub-pixels SP may generate light corresponding to the data signals, and the display panel DP may display an image.

In embodiments, the gate driver 120 and the data driver 130 may include complementary metal-oxide semiconductor (CMOS) circuit elements.

The voltage generator 140 may operate in response to a voltage control signal VCS from the controller 150. The voltage generator 140 may be configured to generate a plurality of voltages and provide the generated voltages to components of the display device DD, such as the gate driver 120, the data driver 130, and the controller 150. The voltage generator 140 may generate a plurality of voltages by receiving an input voltage from outside the display device DD and regulating the received voltage.

The voltage generator 140 may generate a first power voltage and a second power voltage. The first and second power voltages may be provided to the sub-pixels SP through power lines PL. In other embodiments, at least one among the first and second power voltages may be provided from outside the display device DD.

In addition, the voltage generator 140 may provide various voltages and/or signals. For example, the voltage generator 140 may provide one or more initialization voltages applied to sub-pixels SP. For example, in a sensing operation for sensing electrical characteristics of transistors and/or light emitting elements of the sub-pixels SP, a specific reference voltage may be applied to the first to n-th data lines DL1 to DLn, and the voltage generator 140 may generate and transmit the reference voltage to the data driver 130. For example, in a display operation for displaying an image on the display panel DP, pixel control signals may be commonly applied to the sub-pixels SP, and the voltage generator 140 may generate the pixel control signals. In embodiments, the voltage generator 140 may provide the pixel control signals to sub-pixels SP through pixel control lines PXCL. Although the pixel control lines PXCL are shown in FIG. 1 as being connected between the voltage generator 140 and the display panel DP, embodiments are not limited thereto. For example, the pixel control lines PXCL may be connected between the gate driver 120 and the display panel DP. In this case, the pixel control signals may be transmitted from the voltage generator 140 to the pixel control lines PXCL via the gate driver 120.

The controller 150 controls various operations of the display device DD. The controller 150 receives input image data IMG and a control signal CTRL corresponding to the image data IMG from the outside. The controller 150 may provide the gate control signal GCS, the data control signal DCS, and the voltage control signal VCS in response to the control signal CTRL.

The controller 150 may convert the input image data IMG to be suitable for the display device DD or the display panel DP and output the image data DATA. In embodiments, the controller 150 may output the image data DATA by arranging the input image data IMG to fit the sub-pixels SP in rows.

Two or more components among the data driver 130, the voltage generator 140, and the controller 150 may be mounted in one integrated circuit. As shown in FIG. 1, the data driver 130, the voltage generator 140, and the controller 150 may be included in a driver integrated circuit (DIC). In this case, the data driver 130, the voltage generator 140, and the controller 150 may be functionally distinct components within one driver integrated circuit (DIC). In other embodiments, at least one among the data driver 130, the voltage generator 140, and the controller 150 may be provided as a component separate from the driver integrated circuit (DIC).

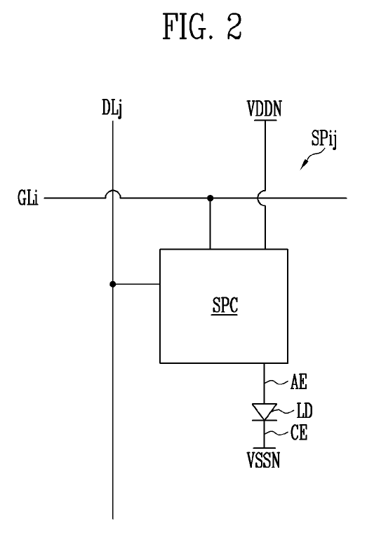

FIG. 2 is a block diagram illustrating an embodiment of any one of the sub-pixels of FIG. 1. In FIG. 2, among the sub-pixels SP of FIG. 1, a sub-pixel SPij arranged in an i-th row (i is an integer greater than or equal to 1 and less than or equal to m) and a j-th column (j is an integer greater than or equal to 1 and less than or equal to n) is exemplarily shown.

Referring to FIG. 2, the sub-pixel SPij may include a sub-pixel circuit SPC and a light emitting element LD.

The light emitting element LD is connected between a first power voltage node VDDN and a second power voltage node VSSN. The first power voltage node VDDN is connected to one of the power supply lines PL of FIG. 1 to receive a first power voltage. The second power voltage node VSSN is connected to another one of the power supply lines PL of FIG. 1 to receive a second power voltage. The first power voltage may have a higher voltage level than the second power voltage.

The light emitting element LD is connected between an anode electrode AE and a cathode electrode CE. The anode electrode AE may be connected to the first power voltage node VDDN through the sub-pixel circuit SPC. For example, the anode electrode AE may be connected to the first power voltage node VDDN through one or more transistors included in the sub-pixel circuit SPC. The cathode electrode CE may be connected to the second power voltage node VSSN. The light emitting element LD is configured to emit light according to a current flowing from the anode electrode AE to the cathode electrode CE.

The sub-pixel circuit SPC may be connected to an i-th gate line GLi among the first to m-th gate lines GL1 to GLm of FIG. 1, and a j-th data line DLj among the first to n-th data lines DL1 to DLn of FIG. 1. In response to a gate signal received through the i-th gate line GLi, the sub-pixel circuit SPC controls the light emitting element LD to emit light according to a data signal received through the j-th data line DLj. In embodiments, the sub-pixel circuit SPC may be further connected to the pixel control lines PXCL of FIG. 1. In this case, the sub-pixel circuit SPC may further control the light emitting element LD in response to pixel control signals received through the pixel control lines PXCL.

For such operations, the sub-pixel circuit SPC may include circuit elements, for example, transistors and one or more capacitors.

The transistors of the sub-pixel circuit SPC may include P-type transistors and/or N-type transistors. In embodiments, the transistors of the sub-pixel circuit SPC may include a metal oxide silicon field effect transistor (MOSFET). In embodiments, the transistors of the sub-pixel circuit SPC may include an amorphous silicon semiconductor, a monocrystalline silicon, a polycrystalline silicon semiconductor, an oxide semiconductor, or the like.

FIG. 3 is a plan view illustrating an embodiment of the display device DD of FIG. 1.

Referring to FIG. 3, the display device DD may include a display panel DP and a coating layer CTL stacked on the display panel DP in a third direction DR3 intersecting first and second directions DR1 and DR2. The coating layer CTL may cover the entire display panel DP except for a part of a non-display area NDA in which the driver integrated circuit DIC is disposed. A top surface of the display panel DP may be protected by the coating layer CTL having high impact resistance.

The display device DD may include a display area DA and the non-display area NDA. Accordingly, the display panel DP included in the display device DD may also include the display area DA and the non-display area NDA.

The display panel DP displays an image through the display area DA. The non-display area NDA is located around the display area DA.

The display panel DP includes the sub-pixels SP in the display area DA. The sub-pixels SP may be arranged along the first direction DR1 and the second direction DR2 intersecting the first direction DR1. For example, the sub-pixels SP may be arranged in a matrix form along the first direction DR1 and the second direction DR2. As another example, the sub-pixels SP may be arranged in a zigzag shape along the first direction DR1 and the second direction DR2. The arrangement of the sub-pixels SP may vary according to embodiments. The first direction DR1 may be a row direction, and the second direction DR2 may be a column direction.

Two or more sub-pixels among the plurality of sub-pixels SP may constitute one pixel PXL. In FIG. 3, the pixel PXL is shown to include three sub-pixels SP1 to SP3, but embodiments are not limited thereto. For example, the pixel PXL may include two sub-pixels. Hereinafter, for convenience of description, it is assumed that the pixel PXL includes first to third sub-pixels SP1 to SP3.

Each of the first to third sub-pixels SP1 to SP3 may generate light of one of various colors such as red, green, blue, cyan, magenta, yellow, and the like. Hereinafter, for clear and concise description, it is assumed that the first sub-pixel SP1 is configured to generate red color light, the second sub-pixel SP2 is configured to generate green color light, and the third sub-pixel SP3 generates blue color light.

Each of the first to third sub-pixels SP1 to SP3 may include at least one light emitting element configured to generate light. In embodiments, the light emitting elements of the first to third sub-pixels SP1 to SP3 may generate light of the same color. For example, the light emitting elements of the first to third sub-pixels SP1 to SP3 may generate blue light. In other embodiments, the light emitting elements of the first to third sub-pixels SP1 to SP3 may generate light of different colors from each other. For example, the light emitting elements of the first to third sub-pixels SP1 to SP3 may respectively generate light of a red color, a green color, and a blue color.

As the display panel DP, a self-luminous display panel such as a light emitting diode display panel (LED display panel) using a micro-scale or nano-scale light emitting diode as a light emitting element, an organic light emitting display panel (OLED panel) using an organic light emitting diode as a light emitting element, or the like may be used.

A component for controlling the sub-pixels SP may be located in the non-display area NDA. Wirings connected to the sub-pixels SP, for example, the first to m-th gate lines GL1 to GLm, the first to n-th data lines DL1 to DLn, the power lines PL, and the pixel control lines PXCL of FIG. 1 may be located in the non-display area NDA.

At least one among the gate driver 120, the data driver 130, the voltage generator 140, and the controller 150 of FIG. 1 may be located in the non-display area NDA of the display panel DP. In embodiments, the gate driver 120 may be located in the non-display area NDA. In this case, the data driver 130, the voltage generator 140, and the controller 150 may be implemented as the driver integrated circuit DIC of FIG. 1 separated from the display panel DP, and the driver integrated circuit DIC may be connected to wirings located in the non-display area NDA. In other embodiments, the gate driver 120 may be implemented as one integrated circuit separate from the display panel DP together with the data driver 130, the voltage generator 140, and the controller 150. The driver integrated circuit DIC may be located on one side of the non-display area NDA that is not covered by the coating layer CTL, and may be configured in plural. However, embodiments are not limited thereto, and the coating layer CTL may entirely cover the display panel DP.

In embodiments, the display area DA may have various shapes. The display area DA may have the shape of a closed loop including straight and/or curved sides. For example, the display area DA may have shapes such as a polygon, a circle, a semicircle, an ellipse, and the like.

In embodiments, the display panel DP may have a flat display surface. In other embodiments, the display panel DP may have an at least partially rounded display surface. In embodiments, the display panel DP may be bendable, foldable, or rollable. In such cases, the display panel DP and/or a substrate of the display panel DP may include materials having a flexible property.

In embodiments, the coating layer CTL may have a shape in which at least one region is inclined (or tapered). The coating layer CTL may include a main area MA and a sub area SA that are distinguished from the display area DA and the non-display area NDA of the display panel DP.

The main area MA may be a flat area and overlap the display area DA and a portion of the non-display area NDA of the display panel DP.

The sub area SA may be a region inclined downward from at least one edge of the main area MA, and may overlap only with the non-display area NDA. That is, the sub area SA may not overlap the display area DA.

For example, the sub area SA may include a first sub area SA1, a second sub area SA2, and a third sub area SA3. The first sub area SA1 may be located to a left side in the first direction DR1 of the main area MA, the second sub area SA2 may be located to a right side in the first direction DR1 of the main area MA, and the third sub area SA3 may be located to an upper side in the second direction DR2 of the main area MA. That is, each of the first to third sub areas SA1 to SA3 may be positioned in a shape inclined downward from three edges of the main area MA. Because the coating layer CTL is not located in the non-display area NDA in which the driver integrated circuit DIC is located, the sub area SA may not be located in a lower side in the second direction DR2 of the main area MA. However, embodiments are not limited thereto.

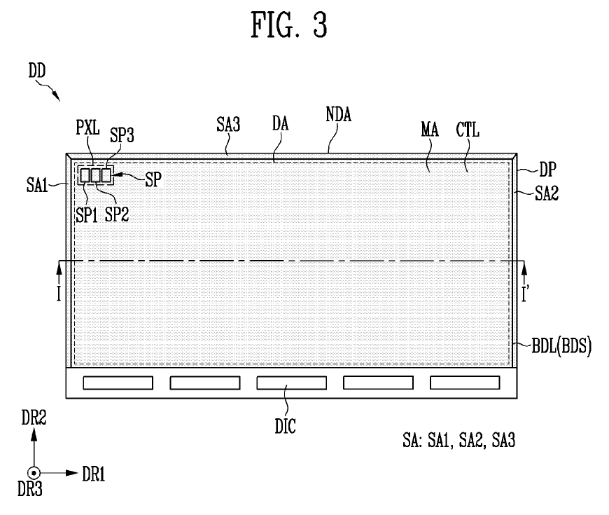

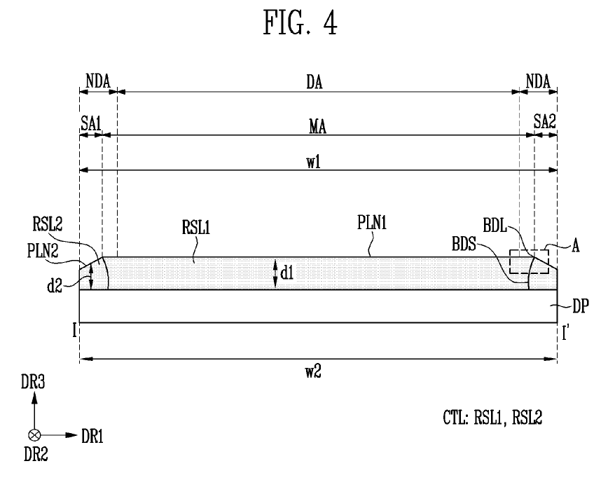

FIG. 4 is a cross-sectional view illustrating an embodiment of the display device of FIG. 3.

Referring to FIGS. 3 and 4, the coating layer CTL may be disposed on the display panel DP. The display panel DP and the coating layer CTL may be in contact with each other as a whole, i.e., may be in direct contact with one another. A top surface of the display panel DP and a bottom surface of the coating layer CTL facing each other may be in contact with each other as a whole. That is, a separate layer or member such as an optical film OF (see FIG. 16) may not be interposed between the display panel DP and the coating layer CTL.

The coating layer CTL may have an upper surface including a first plane PNL1 located at a central portion of the coating layer CTL and a second plane PNL2 located at at least one edge of the coating layer CTL. The second plane PNL2 may be configured as a plane inclined with respect to the first plane PNL1. For example, the second plane PNL2 may be located at three edges of the coating layer CTL. However, embodiments are not limited thereto.

The first plane PNL1 may correspond to the main area MA of the coating layer CTL, and the second plane PNL2 may correspond to the sub area SA of the coating layer PTL. Accordingly, the second plane PNL2 may not overlap the display area DA of the display panel DP, but may overlap only the non-display area NDA. However, embodiments are not limited thereto.

A distance d2 from the display panel DP to the second plane PNL2 may be less than or equal to a distance d1 from the display panel DP to the first plane PNL1. Further, the distance d2 from the display panel DP to the second plane PNL2 may decrease as a distance from the first plane PNL1 increases. That is, a cross-sectional shape of the coating layer CTL may be a regular tapered shape.

The first plane PNL1 and the second plane PNL2 may form a boundary line at a portion connected to each other. That is, the first plane PNL1 and the second plane PNL2 may be connected to each other without a step. Accordingly, a top surface of the coating layer CTL may extend from the first plane PNL1 to the second plane PNL2 without a step.

A width w2 of the display panel DP in the first direction DR1 and the width w1 of the coating layer CTL in the first direction DR1 may be substantially the same. Specifically, an end of an edge of the coating layer CTL in which the second plane PNL2 of the coating layer PTL is present and an end of the display panel DP may coincide with each other. Because the coating layer CTL is formed in a state in which a side surface of the display panel DP is pressed in the manufacturing method to be described later, the end of the edge of the coating layer CTL and the end of the display panel DP may coincide with each other.

The coating layer CTL may include a first resin layer RSL1 and a second resin layer RSL2.

In embodiments, the first resin layer RSL1 may be disposed at the central portion on the display panel DP. The first resin layer RSL1 may correspond to the main area MA. The second resin layer RSL2 may be disposed at at least one edge on the display panel DP. For example, the second resin layer RSL2 may be disposed at three edges on the display panel DP. The second resin layer RSL2 corresponds to the sub area SA, so that the second resin layer RSR2 does not overlap the display area DA of the display panel DP, but only overlaps the non-display area NDA.

In embodiments, the first resin layer RSL1 may have the first plane PNL1 as an upper surface. The second resin layer RSL2 may have the second plane PNL2 as an upper surface. However, the embodiments are not limited thereto, and because the second plane PNL2 is defined as a portion of the upper surface of the coating layer CTL that is inclined from the first plane PNL1 or has a surface characteristic different from that of the first plane PML1, the first resin layer RSL1 and the first plane PNL1 may not completely correspond to each other, and the second resin layer RSL2 and the second plane PNL2 may not completely corresponds to each other. Hereinafter, for convenience of description, description will be made assuming that the first resin layer RSL1 and the first plane PNL1 completely correspond to each other, and the second resin layer RSL2 and the second plane PNL2 completely correspond to each another.

The thickness d2 of the second resin layer RSL2 may be less than or equal to the thickness d1 of the first resin layer RSL1. Further, the thickness d2 of the second resin layer RSL2 may decrease as a distance from the first resin layer RSL1 increases. However, the thickness d2 of the second resin layer RSL2 may decrease as a distance from the first resin layer RSL1 increases within the extent that a side surface of the edge of the second resin layers RSL2 exists. That is, the cross-sectional shape of the coating layer CTL may be a hexagonal shape rather than a trapezoidal shape. The end of the edge of the second resin layer RSL2 and the end of the display panel DP may coincide with each other.

The first resin layer RSL1 and the second resin layer RSL2 may be in contact with each other. Specifically, a side surface of the first resin layer RSL1 and a side surface of a second resin layer RSL2 may be in contact with each other. In this case, a boundary surface BDS between the first resin layer RSL1 and the second resin layer RSL2 may be formed of a curved surface, i.e., may be a curved surface. Further, a boundary line BDL between the first plane PNL1 and the second plane PNL2 may be a part of the boundary surface BDS between the first resin layer RSL1 and the second resin layer RSL2.

Each of the first resin layer RSL1 and the second resin layer RSL2 may include urethane acrylate. However, because the first resin layer RSL1 and the second resin layer RSL2 are individually formed, physical characteristics of the first resin layer RSL1 and the second resist layer RSL2 may be different from each other by a manufacturing process to be described later. However, embodiments are not limited thereto, and each of the first resin layer RSL1 and the second resin layer RSL2 may include a material other than urethane acrylate.

In embodiments, a degree of hardening of the second resin layer RSL2 may be greater than a degree of hardening of the first resin layer RSL1. Accordingly, a modulus of the second resin layer RSL2 may be greater than a modulus of the first resin layer RSL1.

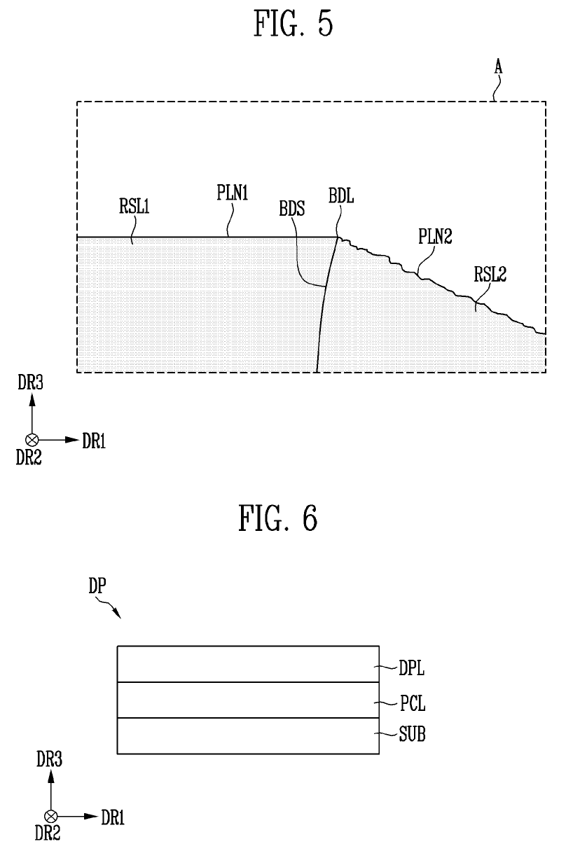

FIG. 5 is an enlarged cross-sectional view illustrating a region A of FIG. 4.

Referring further to FIG. 5, a roughness of the first plane PNL1 may be different from a roughness of a second plane PNL2. Because the first plane PNL1 and the second plane PNL2 are formed in different ways, surface characteristics may be different from each other. Because the second plane PNL2 is a portion formed by cutting through a laser unlike the first plane PNL1 as will be described later, the roughness of the second plane PNL2 may be greater than the roughness of the first plane PNL1.

In embodiments, the coating layer CTL is disposed on the display panel DP to protect the display panel DP, and the second plane PNL2 inclined from the first plane PNL1, which is a flat portion of the coating layer CTL, overlaps only with the non-display area NDA, so that the coating layer CTL may protect the display panel DP without a problem of poor visibility and improve an impact resistance of the display device DD. In addition, when the coating layer CTL is disposed to protect the display panel DP, a separate member other than the coating layer CTL is not required, so that a thickness of the display device DD may be reduced.

FIG. 6 is a cross-sectional view illustrating an embodiment of the display panel DP of FIG. 4.

Referring to FIG. 6, the display panel DP may include a substrate SUB, a pixel circuit layer PCL, and a display element layer DPL which are sequentially stacked on the substrate SUB in a third direction DR3.

The substrate SUB may be made of an insulating material such as glass or resin. For example, the substrate SUB may include a glass substrate. As another example, substrate SUB may include a polyimide (PI) substrate. As another example, the substrate SUB may include a silicon wafer substrate formed using a semiconductor process.

In an embodiment, the substrate SUB may be made of a material that is flexible to allow bending or folding, and may have a single-layer structure or a multi-layer structure. For example, the flexible material may include at least one among polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. However, embodiments are not limited thereto.

The pixel circuit layer PCL is disposed on the substrate SUB. The pixel circuit layer PCL may include insulating layers, and semiconductor electrodes and conductive electrodes disposed between the insulating layers. The conductive electrodes of the pixel circuit layer PCL may function as circuit elements, wirings, or the like.

The circuit elements of the pixel circuit layer PCL may include the sub-pixel circuit SPC (see FIG. 2) of each of the sub-pixels SP of FIG. 3. In other words, circuit elements of the pixel circuit layer PCL may be provided with transistors and one or more capacitors of the sub-pixel circuit SPC.

The wirings of the pixel circuit layer PCL may include wirings connected to the sub-pixels SP. The wirings of the pixel circuit layer PCL may include various signal lines and/or voltage lines necessary for driving the display element layer DPL.

The display element layer DPL is disposed on the pixel circuit layer PCL. The display element layer DPL may include light emitting elements of the sub-pixels SP and an encapsulation layer covering the light emitting elements. The encapsulation layer may directly contact the coating layer CTL.

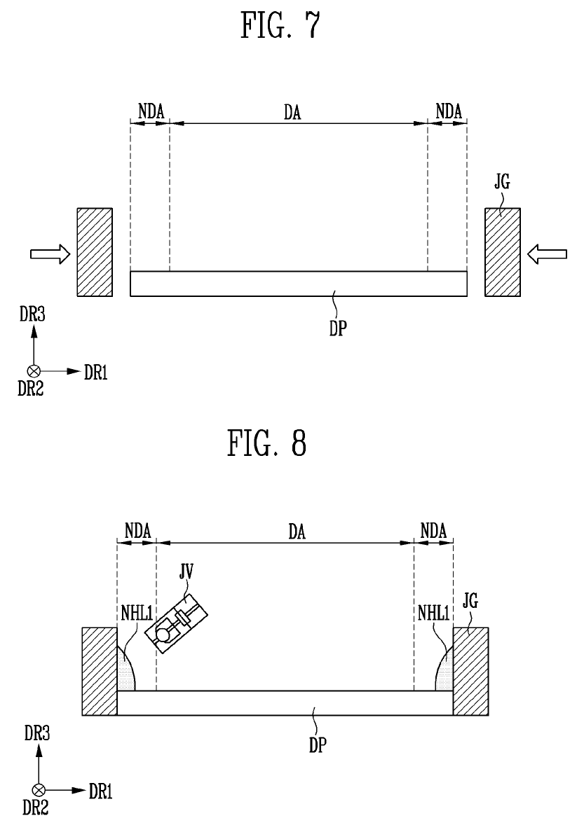

FIGS. 7 to 14 are diagrams illustrating a method of manufacturing a display device according to an embodiment of the present disclosure.

A manufacturing method described with reference to FIGS. 7 to 14 may be a method of manufacturing the display device described with reference to FIG. 1 to FIG. 6. Accordingly, redundant descriptions may be omitted or simplified.

Referring to FIG. 7, the display panel DP including the display area DA and the non-display area NDA around the display area DA may be formed. Specifically, the substrate SUB, the pixel circuit layer PCL, and the display element layer DPL of FIG. 6 may be sequentially formed.

A jig JG may surround at least one side surface of the display panel DP to form a coating layer on the display panel DP. For example, the jig JG may surround only three side surfaces of the display panel DP where the sub area SA of FIG. 3 is located. After jig JG surrounds display panel DP, jig JG may press a side surface of display panel DP. Accordingly, the jig JG may fix the display panel DP without a gap between the jig JG and the display panel DP.

A surface of the jig JG in direct contact with a side surface of the display panel DP may be coated. In this case, the surface of the jig JG may be coated with fluorine or a silicone-based polymer. Accordingly, the jig JG may be easily detached from the coated material even when a material constituting the coating layer is applied on the surface of the jig JG.

Referring to FIGS. 8 to 10, a preliminary resin layer PRSL may be formed on an edge of the display panel DP inside the jig JG. That is, the preliminary resin layer PRSL may be formed on the display panel DP to overlap an edge of the display panel DP, and an end of the display panel DP may coincide with an end of the preliminary resin layer PRSL due to the jig JG.

Referring to FIG. 8, the preliminary resin layer PRSL may be formed by a jetting valve method, a jetting dispensing method, an EHD (Electrohydro Dynamic) method, or the like. For example, a jetting valve JV may apply urethane acrylate to the inside of the jig JG to form a first non-hardened layer NHL1 on the edge of the display panel DP. However, embodiments are not limited thereto, and the first non-hardened layer NHL1 may be formed of a material other than urethane acrylate.

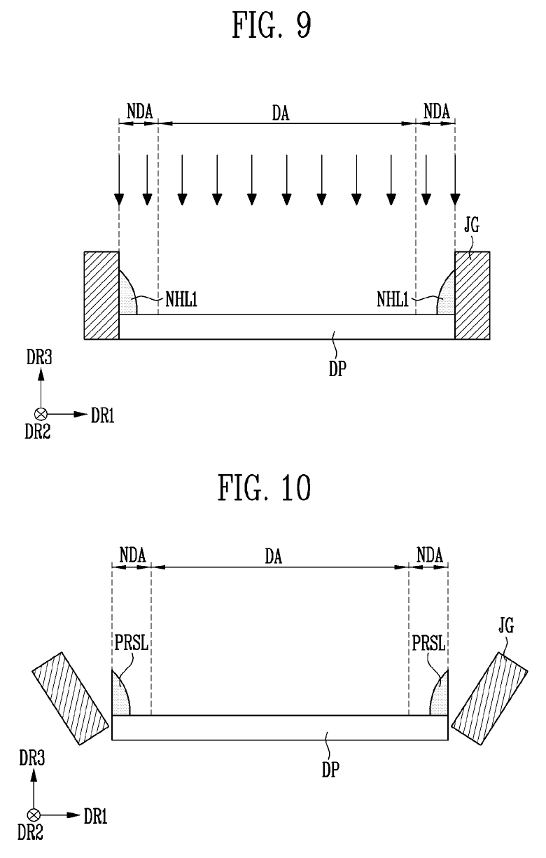

Referring to FIG. 9, the first non-hardened layer NHL1 may be hardened. In this case, the first non-hardened layer NHL1 may be hardened through ultraviolet hardening or thermal hardening to form the preliminary resin layer PRSL.

In this case, because the preliminary resin layer PRSL is a layer formed by applying urethane acrylate only to an edge on the display panel DP inside the jig JG, the surface may have a curved shape.

Referring to FIG. 10, after the preliminary resin layer PRSL is formed, the jig JG may be removed from the display panel DP and the preliminary resin layer PRSL. In this case, because the surface of the jig JG is coated, the jig JG may be easily detached from the preliminary resin layer PRSL.

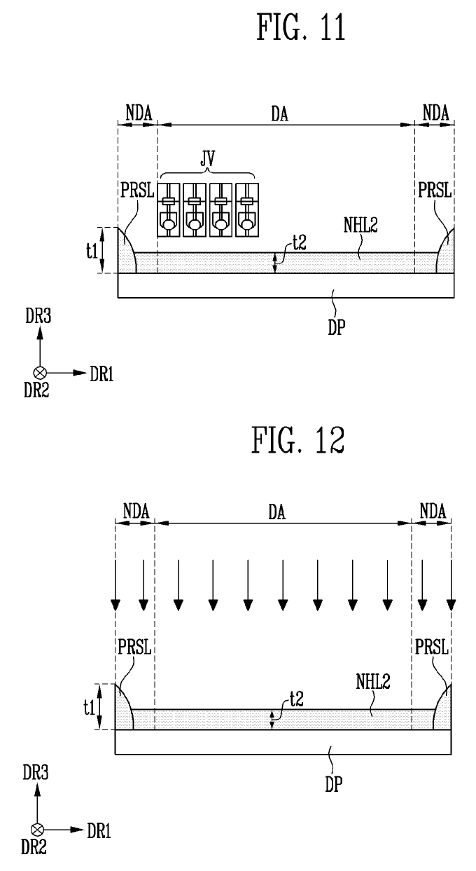

Referring to FIGS. 11 to 13, a first resin layer RSL1 may be formed in a central portion of the display panel DP inside the preliminary resin layer PRSL.

Referring to FIG. 11, the first resin layer RSL1 may be formed by a jetting valve method, a jetting dispensing method, an EHD (Electrohydro Dynamic) method, or the like. For example, a jetting valve JV may apply urethane acrylate to form a second non-hardened layer NHL2 inside the preliminary resin layer PRSL and at a central portion on the display panel DP. However, embodiments are not limited thereto, and the second non-hardened layer NHL2 may be formed of a material other than urethane acrylate.

A thickness t2 of the first resin layer RSL1 may be formed to be smaller than a thickness t1 of the preliminary resin layer PRSL. That is, the first resin layer RSL1 may be formed so that the preliminary resin layer PRSL protrudes from the first resin layer RSL1. Suitably, the first resin layer RSL1 may be formed to have a thickness of about 3 mm or more smaller than that of the preliminary resin layer PRSL. Accordingly, when a part of the preliminary resin layer PRSL is removed thereafter, a part of the preliminary resin layer PRSL may be easily cut.

Referring to FIG. 12, the second non-hardened layer NHL2 may be hardened. In this case, the second non-hardened layer NHL2 may be hardened through ultraviolet hardening or thermal hardening to form the first resin layer RSL1.

Further, as the second non-hardened layer NHL2 is hardened, the preliminary resin layer PRSL may be hardened once more. Accordingly, hardening degrees of each of the preliminary resin layer PRSL and the first resin layer RSL1 may be different from each other. Specifically, the hardening degree of the preliminary resin layer PRSL may be greater than the hardening degree of the first resin layer RSL1, and thus, modulus of the preliminary resin layer PRSL may be larger than modulus of the first resin layer RSL1.

In this case, because the first resin layer RSL1 is formed inside the preliminary resin layer PRSL, the first resin layer RSL1 may be in direct contact side-to-side with the preliminary resin layer PRSL.

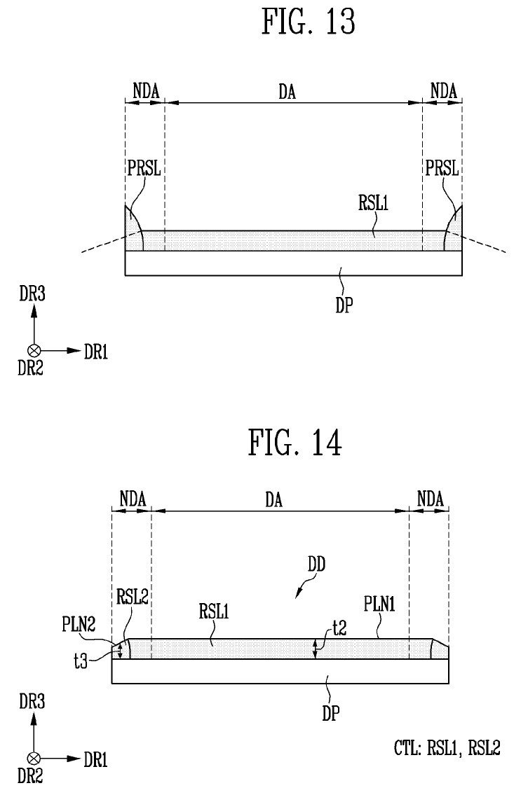

Referring to FIG. 13, the second resin layer RSL2 may be formed by removing a portion of the preliminary resin layer PRSL. In this case, a portion of the preliminary resin layer PRSL may be cut and removed using a laser. Accordingly, the first resin layer RSL1 having the first plane PNL1, which is flat, as an upper surface and a second resin layer RSL2 having the second plane PNL2 inclined from the first plane PNL1 as an upper surface may be formed.

In this case, the preliminary resin layer PRSL may be cut within a range that a side surface of an edge of the preliminary resin layer PRSL exists. In addition, a portion of the first resin layer RSL1 may also be cut together with a portion of the preliminary resin layer PRSL.

Referring to FIG. 14, a coating layer CTL including the first resin layer RSL1 and the second resin layer RSL2 and having the first plane PNL1 and the second plane PNL2 as an upper surface may be formed.

Because the first plane PNL1 has not undergone mechanical deformation since a material constituting the first resin layer RSL1 is applied and hardened, a roughness of a surface may be relatively small. Because the second plane PNL2 is cut using a laser and undergoes heat and mechanical deformation, a roughness of a surface may be relatively greater than the roughness of the first plane PNL1.

In addition, because the second resin layer RSL2 is formed in a tapered shape from the first plane PNL1 of the first resin layer RSL1, the thickness t2 of the first resin layers RSL1 may be greater than or equal to a thickness t3 of the second resin layers RSL2.

Accordingly, a coating layer CTL including the first resin layer RSL1 and the second resin layer RSL2 may be formed, and a display device DD including the coating layer CTL and the display panel DP may be formed.

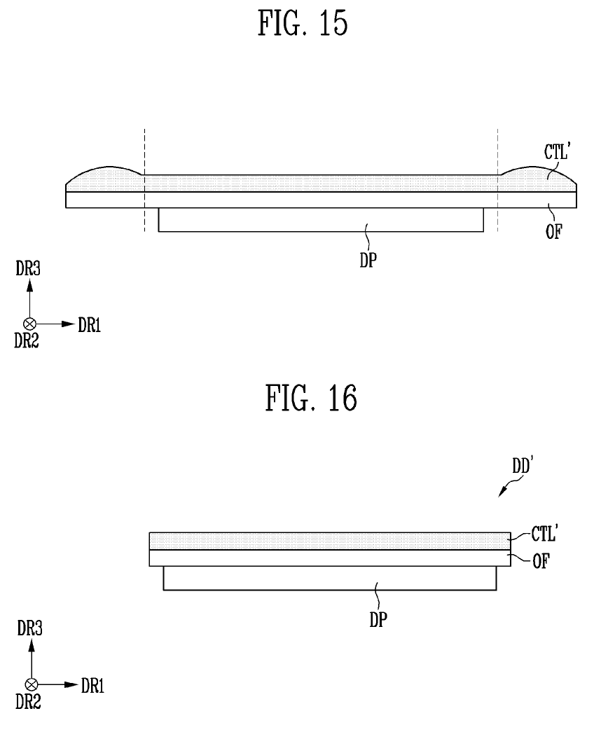

FIGS. 15 and 16 are cross-sectional views illustrating a method of manufacturing a display device DD’ according to a comparative example.

Referring to FIGS. 15 and 16, the display device DD′ according to a conventional comparative example may include a display panel DP, a coating layer CTL′ disposed on the display panel DP, and an optical film OF disposed between the display panel DP and the coating layer CTL’.

Referring to FIG. 15, when the coating layer CTL′ is formed on the display panel DP, an edge bead, at least a portion of which protrudes from a top surface, may be formed at an edge of the coating layer CTL′. Because the edge bead is formed on the edge of the coating layer CTL′, non-uniformity of a thickness of the coating layer CTL′ occurs, and thus visibility of an edge portion of the display device DD′ may be reduced.

In order to prevent decrease in visibility of the edge portion of the display device DD′, the optical film OF that entirely covers the display panel DP and has a larger area than the display panel DP may be disposed on the display panel DP. The coating layer CTL′ is disposed on the optical film OF, and the coating layer CTL' may also be formed to have a larger area than the display panel DP.

Referring further to FIG. 16, an edge bead portion of the coating layer CTL′ that does not overlap the display panel DP may be removed. In this case, the edge bead portion of the coating layer CTL′ may be cut using a laser, but the coating layer CTL′ and the optical film OF may be cut so as to protrude from the display panel DP according to precision of the laser. In this case, portions of the optical film OF and the coating layer CTL′ protruding from the display panel DP may be lifted. Accordingly, a problem that a layer (e.g., a polarizing film) attached on the coating layer CTL′ is lifted may occur.

Although FIG. 16 shows that the edge bead portion of the coating layer CTL′ of FIG. 15 are all removed, when the edge bead is formed to overlap the display panel DP, the edge bead may remain on the display panel DP even after the coating layer CTL′ and the optical film OF are partially removed. Even in this case, a problem that a layer (e.g., a polarizing film) attached on the coating layer CTL′ is lifted may occur.

In order to solve such a problem, in the display device DD according to the embodiments, the coating layer CTL may be directly formed on the display panel DP without a separate member by separately forming the second resin layer RSL2 formed on the edge of the display device DD and the first resin layer RSL1 formed inside the second resin layer RSL2. That is, the display device DD may not include a separate layer or member such as an optical film (see FIG. 16) between the display panel DP and the coating layer CTL. In addition, the coating layer CTL without the edge bead may be formed on the edge.

In addition, in embodiments, when the coating layer CTL is formed to compensate for impact resistance of the display panel DP, because only one layer of the coating layer CTL is disposed on the display panel DP and a separate configuration is not required, thickness of a product is reduced, and the manufacturing process may be simplified. As a result, manufacturing cost for manufacturing the product is reduced, and thus manufacturing efficiency may be improved. In addition, because the coating layer CTL is entirely coated on the display panel DP and is formed by cutting edges of the coating layers CTL disposed in the non-display area NDA, poor visibility due to lifting of configuration on the display panel DP may be improved.

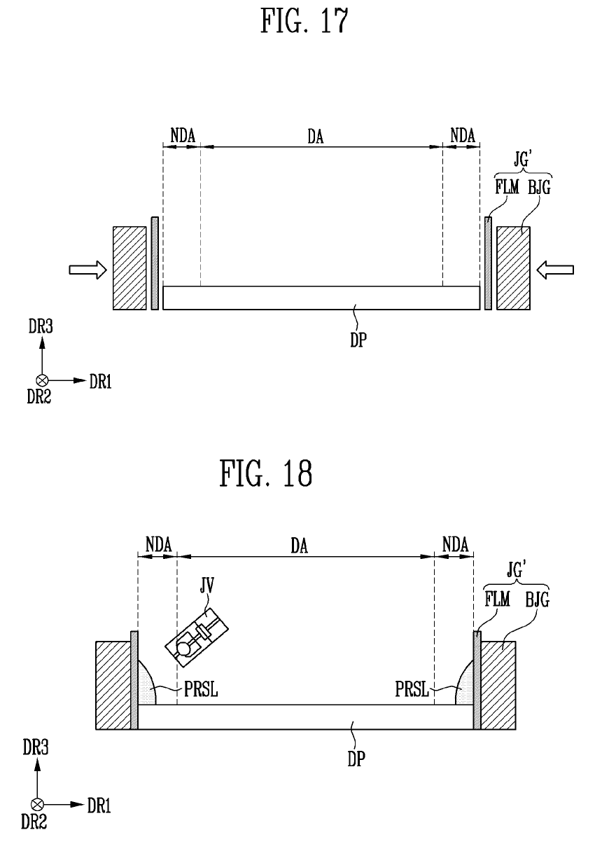

FIGS. 17 to 20 are diagrams illustrating a method of manufacturing a display device according to an embodiment of the present disclosure. The embodiment of FIGS. 17 to 20 may be different from the embodiment of FIGS. 7 to 14 in a structure of the jig JG. Accordingly, redundant descriptions may be omitted or simplified.

Referring to FIG. 17, a jig JG′ may surround at least one side surface of the display panel DP to form a coating layer on the display panel DP.

In embodiments, the jig JG′ may include a base jig BJG and a release film FLM. The release film FLM may be adsorbed to the base jig BJG, by creating a vacuum state using a vacuum hole penetrating the base jig BJG. The release film FLM may be formed of a fluorine- or silicone-based polymer, or may be formed by coating a surface with a fluorine- or silicone-based polymer. Accordingly, the jig JG′ may be easily detached from a coated material even when a material constituting the coating layer is subsequently applied on a surface of the release film FLM.

After the jig JG′ surrounds the display panel DP, the jig JG′ may press the side surface of the display panel DP. Accordingly, the jig JG′ may fix the display panel DP without a gap between the jig JG′ and the display panel DP.

Referring to FIG. 18, a preliminary resin layer PRSL may be formed on an edge of the display panel DP inside the jig JG′. That is, the preliminary resin layer PRSL may be formed on the display panel DP to overlap an edge of the display panel DP, and an end of the display panel DP may coincide with an end of the preliminary resin layer PRSL due to the jig JG′.

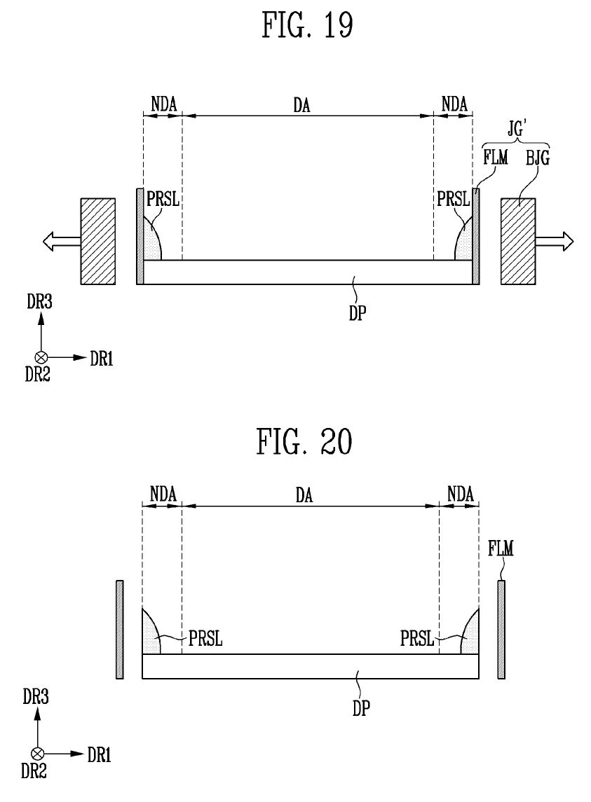

Referring to FIG. 19, after the preliminary resin layer PRSL is formed, the jig JG′ may be removed from the release film FLM. In this case, the vacuum state of the base jig BJG is released through the vacuum hole, so that the base jig BJG may be detached from the release film FLM.

Referring to FIG. 20, after the base jig BJG is detached, the release film FLM may be removed from the display panel DP and the preliminary resin layer PRSL. In this case, because the surface of the release film FLM is coated, the release film FLM may be easily detached from the preliminary resin layer PRSL.

The display device according to an embodiment may be applied to various electronic devices. The electronic device according to an embodiment includes the above-described display device, and may further include a module or device having an additional function other than the display device.

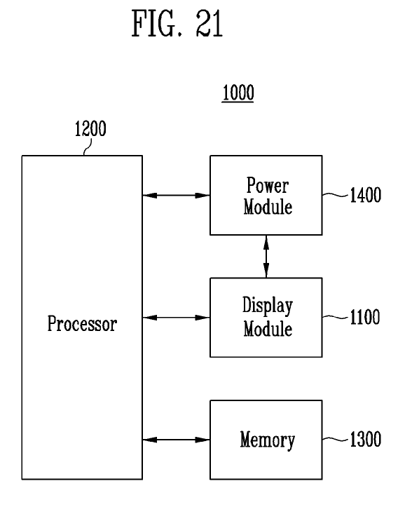

FIG. 21 is a block diagram of an electronic device 1000 according to an embodiment. Referring to FIG. 21, the electronic device 1000 according to an embodiment may include a display module 1100, a processor 1200, a memory 1300, and a power module 1400.

The processor 1200 may include one or more processors and may include at least one among a central processing unit (CPU), an application processor (AP), a graphics processing unit (GPU), a communication processor (CP), an image signal processor (ISP), and a controller.

The memory 1300 may store data information for an operation of the processor 1200 or the display module 1100. When the processor 1200 executes an application stored in the memory 1300, an image data signal and/or an input control signal are transmitted to the display module 1100, and the display module 1100 may process the received signal and output image information through a display screen.

The power module 1400 may include a power supply module such as a power adapter, a battery device, or the like, and a power conversion module that converts power supplied by the power supply module to generate power required for operation of the electronic device 1000.

At least one of the above-described components of the electronic device 1000 may be included in the display device according to the above-described embodiments. In addition, some of the individual modules functionally included in one module may be included in the display device, and other parts may be provided separately from the display device. For example, the display device may include the display module 1100, and the processor 1200, the memory 1300, and the power module 1400 may be provided in the form of other devices in the electronic device 1000 other than the display device.

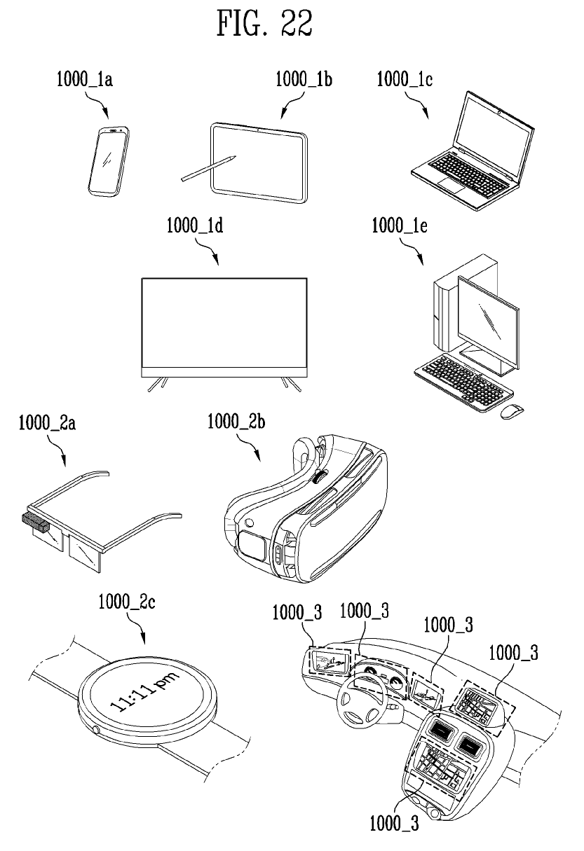

FIG. 22 is a schematic diagram of an electronic device according to various embodiments.

Referring to FIG. 22, various electronic devices to which a display device according to embodiments is applied may include an electronic device for displaying an image, such as a smartphone 1000_1a, a tablet PC 1000_1b, a laptop 1000_1c, a TV 1000_1d, a desk monitor 1000_1e, and the like, as well as a wearable electronic device including a display module, such as smart glasses 1000_2a, a head mounted display 1000_2b, a smart watch 1000_2c, and the like, a vehicle electronic device 1000_3 including a display module such as a CID (Center Information Display) disposed on an instrument panel, a center fascia, and a dashboard of a vehicle, a room mirror display, and the like.

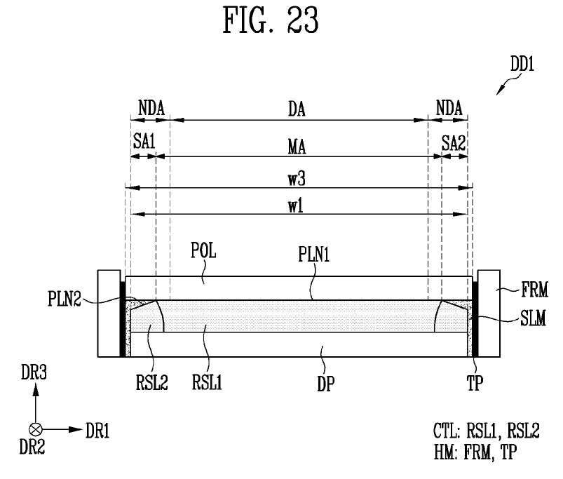

FIG. 23 is a cross-sectional view of a display device DD1 included in an electronic device according to an embodiment. A display panel DP and a coating layer CTL included in the display device DD1 according to an embodiment of FIG. 23 may be substantially the same as the display panel DP and the coating layer CTL included in the display device DD of FIG. 4, respectively. Therefore, redundant descriptions are omitted.

Referring to FIG. 23, the display device DD1 may further include a polarizing film POL, a sealing member SLM, and a housing member HM.

The polarizing film POL may be disposed on the coating layer CTL. The polarizing film POL may reduce reflectance of external light incident on the display panel DP. A width w3 of the polarizing film POL in a first direction DR1 may be greater than a width w1 of the coating layer CTL in the first direction DR1. Accordingly, the polarizing film POL entirely covers the coating layer CTL in the first direction DR1, and an end of the polarizing film POL in the first direction DR1 may protrude from an end of the coating layer CTR in the first direction DR1.

The sealing member SLM may be disposed under the polarizing film POL, and may be disposed between the frame FRM and both the display panel DP and the coating layer CTL on a plane. The sealing member SLM surrounds the display panel DP and the coating layer CTL, and seals the side surfaces of the display panel DP and the coating layer CTL to prevent moisture or foreign matter from penetrating. In addition, the sealing member SLM may be disposed on side surfaces of the display panel DP and the coating layer CTL and under the polarizing film POL. In the manufacturing process, after the polarizing film POL is disposed on the coating layer CTL, the sealing member SLM may be applied under the polarizing film POL and to the side surfaces of the display panel DP and the coating layer CTL. Accordingly, the sealing member SLM may fix the polarizing film POL to the display panel DP and the coating layer CTL.

The display panel DP, the coating layer CTL, and the polarizing film POL may be disposed inside the housing member HM. The housing member HM surrounds the display panel DP, the coating layer CTL, and the polarizing film POL, and may accommodate the display panel DP, the coating layer CTL, and the polarizing film POL. Specifically, the housing member HM may cover side surfaces of each of the display panel DP, the coating layer CTL, and the polarizing film POL.

The housing member HM may include a frame FRM and an adhesive tape TP.

The frame FRM covers the side surfaces of each of the display panel DP, the coating layer CTL, and the polarizing film POL, and may accommodate the display panel DP, the coating layer CTL, and the polarization film POL. The adhesive tape TP is disposed between the frame FRM and the sealing member SLM on a plane, so that the adhesive tape TP may serve to attach the frame FRM to the display panel DP, the coating layer CTL, the sealing member SLM, and the polarizing film POL. That is, a portion of the side surfaces of the sealing member SLM and the polarizing film POL may be attached to the frame FRM through the adhesive tape TP.

The sealing member SLM may overlap only the non-display area NDA and may not overlap the display area DA. In embodiments, the sealing member SLM may only contact the second plane PLN2 and not overlap the first plane PLN1. That is, the sealing member SLM may be in contact only with the second resin layer RSL2 and not with the first resin layer RSL1. However, the present disclosure is not limited thereto.

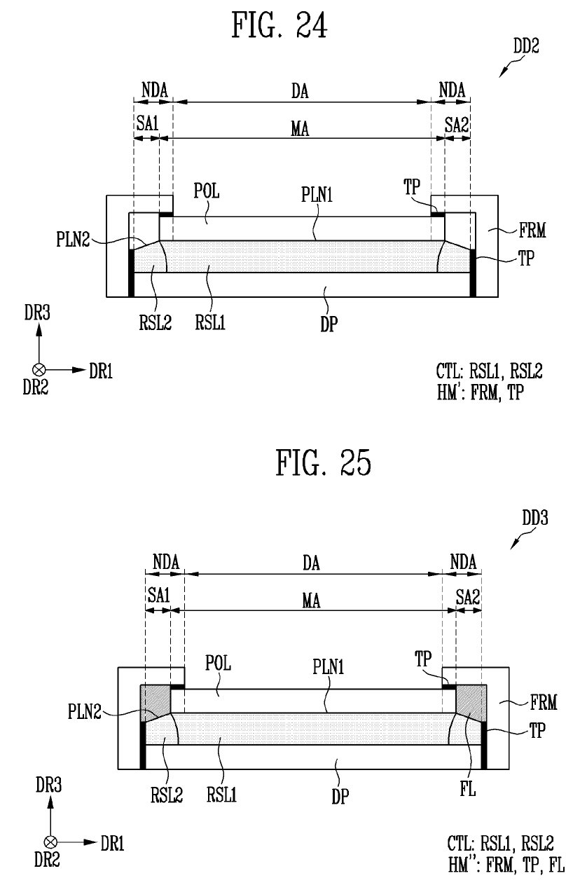

FIG. 24 is a cross-sectional view of a display device DD2 included in an electronic device according to an embodiment. The display device DD2 according to the embodiment of FIG. 24 may be substantially the same as the display device DD1 according to the embodiment in FIG. 23 except for a housing member. Therefore, redundant descriptions are omitted.

Referring to FIG. 24, the display device DD2 may further include a polarizing film POL and a housing member HM′.

The polarizing film POL may be disposed on the coating layer CTL. A width of the polarizing film POL in the first direction DR1 may be smaller than a width of the coating layer CTL in the first direction DR1. Accordingly, an end of the coating layer CTL in the first direction DR1 may protrude from an end of the polarizing film POL in the first direction DR1.

The display panel DP, the coating layer CTL, and the polarizing film POL may be disposed inside the housing member HM′. The housing member HM′ may surround the display panel DP, the coating layer CTL, and the polarizing film POL.

The housing member HM′ may include a frame FRM and an adhesive tape TP.

The frame FRM covers the side surfaces of each of the display panel DP, the coating layer CTL, and the polarizing film POL, and may accommodate the display panel DP, the coating layer CTL, and the polarization film POL. Specifically, the frame FRM may cover a portion of a side surface of each of the display panel DP and the coating layer CTL and a top surface of the polarizing film POL. In this case, the frame FRM may overlap only the non-display area NDA of the display panel DP and may not overlap the display area DA.

The frame FRM may contact a side surface of each of the display panel DP and the coating layer CTL, and may not contact an upper surface of the coating layer CTL. That is, the frame FRM may contact the side surface of the second resin layer RSL2 and may not contact the upper surfaces of the first resin layer RSL1 and the second resin layer RSL2. In addition, the frame FRM may contact a part of the upper surface of the polarizing film POL, and may not contact the rest and the side surface of the polarizing films POL except for the part of the upper surface.

Accordingly, the frame FRM has a shape of “F” in cross section, and an empty space may be formed between a portion of the top surface of the coating layer CTL, the side surface of the polarizing film POL, and the frame FRM.

The adhesive tape TP is disposed between an inner side of the frame FRM, the side surface of each of the coating layer CTL and the display panel DP, and a part of the upper surface of the polarizing film POL, whereby the adhesive tape TP may serve to attach the frame FRM to the display panel DP, the coating layer CTL, and the polarizing film POL to each other. That is, a portion of a side surface of each of the display panel DP and the coating layer CTL, and a top surface of the polarizing film POL may be attached to the frame FRM through the adhesive tape TP. In this case, the adhesive tape TP in contact with a part of the upper surface of the polarizing film POL may further include a cushioning layer for protecting the top surface of the polarizer film POL.

FIG. 25 is a cross-sectional view of a display device DD3 included in an electronic device according to an embodiment. The housing member HM′′ included in the display device DD3 according to an embodiment of FIG. 25 may be substantially the same as the housing member HM' included in the display device DD2 of FIG. 24 except for a filling layer FL. Therefore, redundant descriptions are omitted.

Referring to FIG. 25, the housing member HM′′ of the display device DD3 may further include the filling layer FL.

The filling layer FL may fill an empty space formed between a portion of the top surface of the coating layer CTL, a side surface of the polarizing film POL, and the frame FRM. Accordingly, the filling layer FL may contact only a portion of the inner side of the frame FRM, the side surface of the polarizing film POL, and the top surface of the coating layer CTL. Similarly with the frame FRM, the filling layer FL may overlap only with the non-display area NDA and may not overlap with the display area DA. In this case, the filling layer FL may include a resin.

Although the technical idea of the present disclosure has been described in detail according to the above-described embodiments, it should be noted that the above embodiments are for the purpose of description and not for the purpose of limitation. It will be understood by those skilled in the art that various modifications are possible within the scope of the technical idea of the present disclosure.

The scope of the present disclosure is not limited to the contents described in the detailed description of the specification, but should be determined by the claims. It is to be construed that all changes or modifications derived from the meaning and scope of the claims and their equivalents are included in the scope of the present disclosure.

What is claimed is:

1. A display device comprising:
a display panel including a display area and a non-display area around the display area; and
a coating layer disposed on the display panel, the coating layer having a top surface including a first plane at a central portion of the coating layer, and a second plane inclined with respect to the first plane at at least one edge of the coating layer and overlapping only with the non-display area.

2. The display device of claim 1, wherein a distance from the display panel to the second plane is smaller than or equal to a distance from the display panel to the first plane.

3. The display device of claim 2, wherein the distance from the display panel to the second plane decreases as a distance from the first plane increases.

4. The display device of claim 2, wherein the first plane and the second plane form a boundary line at a portion connected to each other, and
wherein the top surface of the coating layer extends from the first plane to the second plane.

5. The display device of claim 1, wherein a width of the display panel in a first direction is a same as a width of the coating layer in the first direction.

6. The display device of claim 1, wherein an end of an edge of the coating layer on which the second plane of the coating layer exists and an end of the display panel coincide with each other.

7. The display device of claim 1, wherein a roughness of the first plane is different from a roughness of the second plane.

8. The display device of claim 7, wherein the roughness of the second plane is greater than the roughness of a first plane.

9. The display device of claim 1, wherein the coating layer includes:
a first resin layer disposed in the central portion on the display panel; and
a second resin layer disposed on an edge of the display panel and in contact with the first resin layer.

10. The display device of claim 9, wherein the first resin layer has the first plane as an upper surface, and
wherein the second resin layer has the second plane as an upper surface.

11. The display device of claim 10, wherein a boundary line between the first plane and the second plane is a part of a boundary surface between the first resin layer and the second resin layer.

12. The display device of claim 9, wherein each of the first resin layer and the second resin layer include a urethane acrylate, and
wherein a degree of hardening of the second resin layer is greater than a degree of hardening of the first resin layer.

13. The display device of claim 9, wherein a boundary surface between the first resin layer and the second resin layer is a curved surface.

14. The display device of claim 1, wherein the display panel and the coating layer are in direct contact with each other.

15. The display device of claim 1, comprising no optical film between the display panel and the coating layer.

16. A method of manufacturing a display device, comprising:
forming a display panel including a display area and a non-display area around the display area; and
forming a coating layer having a top surface including a first plane at a central portion of the coating layer on the display panel, and a second plane inclined with respect to the first plane and overlapping only with the non-display area at at least one edge of the coating layer.

17. The method of claim 16, wherein forming the coating layer includes:
forming a first resin layer disposed in the central portion on the display panel and having the first plane as an upper surface, and a second resin layer disposed at the edge on the display panel and having the second plane as an upper surface.

18. The method of claim 17, wherein forming the first resin layer and the second resin layer includes:
surrounding at least one side surface of the display panel with a jig, and pressing the at least one side surface of the display panel with the jig;
forming a preliminary resin layer on an edge of the display panel inside the jig;
removing the jig;
forming the first resin layer in a central portion of the display panel inside the preliminary resin layer; and
removing a portion of the preliminary resin layer to form the second resin layer having the second plane inclined from the first plane.

19. The method of claim 18, wherein the first resin layer is formed to have a thickness smaller than a thickness of the preliminary resin layer and larger than a thickness of the second resin layer.

20. An electronic device comprising:
one or more processors; and
a display device configured to display an image under a control of the one or more processors,
wherein the display device includes:
a housing member;
a display panel disposed inside the housing member and including a display area and a non-display area around the display area;
a coating layer disposed inside the housing member, disposed on the display panel, and having a top surface including a first plane at a central portion of the coating layer and a second plane inclined with respect to the first plane at at least one edge of the coating layer and overlapping only with the non-display area; and
a polarizing film disposed inside the housing member and disposed on the coating layer.
